(19) United States
(12) Patent Application Publication
(10) Pub. No.: US 2006/0199306 A1
(43) Pub. Date: Sep. 7, 2006

(54) CHIP STRUCTURE AND MANUFACTURING PROCESS THEREOF

(76) Inventors: Mon-Chin Tsai, Kaohsiung (TW); Jian-Wen Lo, Taipei County (TW); Shao-Wen Fu, Pingtung County (TW); Chi-Yu Wang, Kaohsiung City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/306,054

(22) Filed: Dec. 15, 2005

(30) Foreign Application Priority Data
Feb. 21, 2005 (TW) 94104991

(51) Int. Cl. H01L 21/00; H01L 23/02

(52) U.S. Cl. 438/109; 257/678

(57) ABSTRACT

A chip structure and the manufacturing process thereof are provided. The feature of the present application is that the chip structure has a first passivation layer covering a substrate of the chip and exposing each of bonding pads and a portion of the substrate surface, and a second passivation layer covering the sidewalls of the first passivation layer and the portion of substrate surface exposed by the first passivation layer, to prevent moisture infiltration from the edge of the substrate. Therefore, the reliability of the chip structure is enhanced.

### CROSS-REFERENCE TO RELATED APPLICATION

This application claims the priority benefit of Taiwan application serial no. 94104991, filed on Feb. 21, 2005. All disclosure of the Taiwan application is incorporated herein by reference.

### BACKGROUND OF THE INVENTION

1. Field of Invention

The present invention relates to a chip structure. More particularly, the present invention relates to a chip structure having a plurality of passivation layers and the manufacturing process thereof.

2. Description of Related Art

In the semiconductor industry, the manufacture of the integrated circuits (ICs) can mainly be categorized as three stages: the manufacture of wafers, the manufacture of the ICs and the packaging of the ICs. Furthermore, the dies are formed following the steps of wafer manufacturing, circuit designing, circuit manufacturing and wafer cutting. In general, each of the dies includes a passivation layer covering the surface of the silicon substrate and exposing the position of each bonding pad. The passivation layer not only planarizes the surface of the silicon substrate, but also protects the chip from being adversely influenced by the moisture and alleviates the damage caused by thermal stresses.

Referring to FIG. 1, it shows a schematic partial cross-sectional view of a conventional chip structure. Each of the chip structure that is formed by wafer cutting has a substrate 100 and a plurality of bonding pads 110. The bonding pads 110 are arranged on an active surface 102 of the substrate 100 and electrically connected to the IC in the substrate 100. Furthermore, the active surface 102 of the substrate 100 is covered with a plurality of passivation layers; the passivation layers, for example, consists of a wafer passivation layer 122 made of silicon dioxide or silicon nitride laminated with a plurality of passivation layers 124, 140 made of polyimide. Furthermore, a bump 150 is disposed on each of the bonding pads 110 correspondingly, and an under ball metal layer 130 is employed to increase the bonding reliability for the bonding pads 110.

Referring to the enlarged schematic view of FIG. 1 on the right side, after going through the patterning lithography process, the bottom edge of the outermost passivation layer 140 is likely to be formed with notches or cuts (known as the undercut phenomenon). Because moistures easily infiltrate into the chip structure from the cuts, delamination of the chip structure may occur and the reliability of the products thus becomes worse.

### SUMMARY OF THE INVENTION

The object of the present invention is to provide a chip structure and manufacturing process thereof, in which an improved passivation layer is used to prevent moisture from infiltrating into the chip structure, thereby enhancing the reliability of the chip structure.

A chip structure is provided in the present invention, which comprises a substrate, a plurality of bonding pads, a first passivation layer, a plurality of under ball metal layers and a second passivation layer. The substrate has an active surface, and each of the bonding pads is disposed on the active surface. Furthermore, the first passivation layer is disposed on the active surface and exposes the bonding pads. Moreover, each of the under ball metal layers is connected to one of the bonding pads respectively. The second passivation layer is disposed on the first passivation layer and a portion of the substrate exposed by the first passivation layer, wherein the second passivation layer covers the sidewalls of the first passivation layer, and exposes each of the under ball metal layers.

A wafer structure is provided in the present invention, which comprises a substrate, a plurality of bonding pads, a first passivation layer, a plurality of under ball metal layers and a second passivation layer. The substrate has an active surface, and each of the bonding pads is disposed on the active surface. Furthermore, the first passivation layer is disposed on the active surface and exposes the bonding pads and a portion of the active surface. Moreover, each of the under ball metal layers is connected to one of the bonding pads respectively. The second passivation layer is disposed on the first passivation layer and a portion of the substrate exposed by the first passivation layer, wherein the second passivation layer covers the sidewall of the first passivation layer, and exposes each under ball metal layer.

According to the preferred embodiment of the present invention, the material of the above first passivation layer and second passivation layer is, for example, polyimide (PI) or benzocyclobutene (BCB).

A chip manufacturing process is further provided in the present invention, which comprises the steps of providing a wafer having a substrate, a plurality of bonding pads and a wafer passivation layer, wherein the substrate has an active surface disposed with the bonding pads, and the wafer passivation layer covers the active surface and exposes the bonding pads; forming a first passivation layer on the wafer to cover the wafer passivation layer and the bonding pads, then patterning the first passivation layer so as to expose the bonding pads and a portion of the active surface; forming a plurality of under ball metal layers, and each of the under ball metal layers is connected to one of the bonding pads respectively; finally, forming a second passivation layer on the wafer, and patterning the second passivation layer so as to expose the under ball metal layers and a portion of the active surface exposed by the first passivation layer, wherein the second passivation layer covers the sidewall of the first passivation layer.

According to the preferred embodiment of the present invention, the above chip structure further comprises a plurality of redistribution layers disposed between the first passivation layer and the second passivation layer, and each of the redistribution layers is connected to one of the bonding pads and one of the under ball metal layers respectively.

According to the preferred embodiment of the present invention, the above chip manufacturing process further comprises forming a plurality of redistribution layers before the under ball metal layers are formed, in which the redistribution layers are disposed between the first passivation layer and the second passivation layer, and each of the redistribution layers is connected to one of the bonding pads and one of the under ball metal layers respectively.

The design of the second passivation layer for covering the sidewall of the first passivation layer is employed in the present invention, preventing moisture infiltration from the substrate edge and the delamination. Therefore, the reliability of the chip structure can be enhanced effectively.

In order to the make the aforementioned and other objects, features and advantages of the present invention comprehensible, the preferred embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view and an enlarged schematic partial view of a conventional chip structure.

FIG. 2 is a schematic cross-sectional view and an enlarged partial schematic view of a chip structure in a preferred embodiment of the present invention.

FIG. 3 is a schematic cross-sectional view of a chip structure in another embodiment of the present invention.

FIG. 4 to FIG. 6 are schematic views of the backend manufacturing processes of the chip structure in a preferred embodiment of the present invention sequentially.

### DESCRIPTION OF EMBODIMENTS

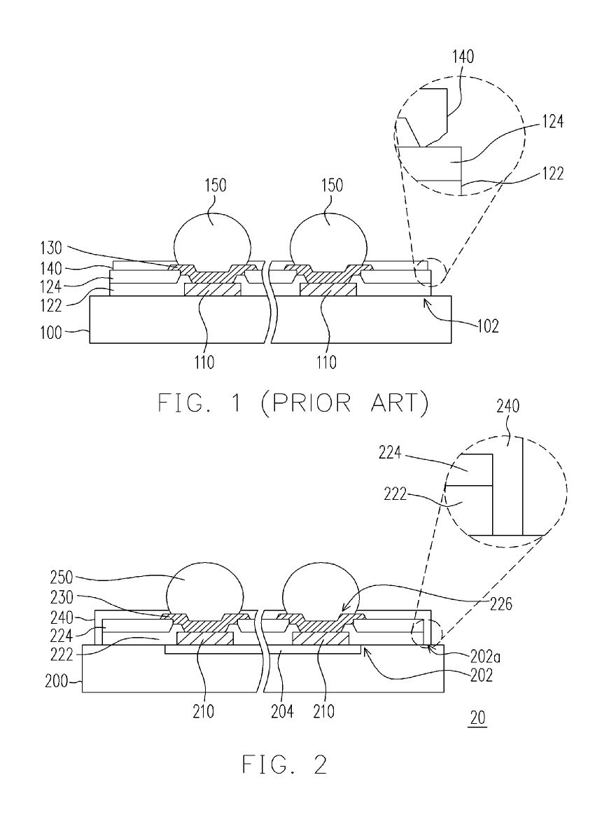

Referring to FIG. 2, it is a schematic partial cross-sectional view of a chip structure in a preferred embodiment of the present invention. In the present embodiment, the chip structure 20 mainly comprises a substrate 200, a plurality of bonding pads 210, a first passivation layer 224, a plurality of under ball metal layers 230 and a second passivation layer 240. The substrate (e.g. silicon) 200 has at least a circuitry unit 204 including IC layouts. The circuitry unit 204 is located in the substrate 200, and bonding pads 210 are disposed on an active surface 202 of the substrate 200. Each of the bonding pads 210 is disposed on the circuitry unit 204 and electrically connected to the ICs. Furthermore, the first passivation layer 224 is formed on the active surface 202 of the substrate 200. Then, a portion of the first passivation layer 224 is removed through a patterning process, such that each of the bonding pads 210 and a portion of the active surface 202a are exposed by the first passivation layer 224.

In the present embodiment, the first passivation layer 224 can cover a wafer passivation layer 222 made of, for example, silicon dioxide or silicon nitride. The material of the first passivation layer 224 is, for example, polyimide or benzocyclobutene (BCB). The wafer passivation layer 222 is a preformed passivation layer over the wafer before the wafer being dispatched from the factory. The first passivation layer 224 has a plurality of first openings that expose the corresponding bonding pads 210 and the first opening can be considered as a bonding pad contact window 226. Therefore, in the succeeding bumping process, an under ball metal layer 230 can be formed at the position defined by the bonding pad contact window 226. The bonding strength of the plated or printed bump 250 is increased through the bonding capability of the under ball metal layer 230 and the bonding pad 210.

It should be noted that the second passivation layer 240 covers the first passivation layer 224 and around the under ball metal layer 230 and the bump 250, so as to further protect the under ball metal layer 230 and alleviate the thermal stress to the bump 250. Moreover, the second passivation layer 240 covers the sidewall of the first passivation layer 224 and the active surface edge 202a exposed by the first passivation layer 224, to prevent moisture infiltration from the edge of the substrate 200, thereby enhancing the reliability of the chip structure.

Referring to the enlarged partial schematic view of FIG. 2, the covering area of the second passivation layer 240 extends downward to the sidewalls of the wafer passivation layer 222 and the first passivation layer 224, and reaches the active surface 202 of the substrate 200. Therefore, the moisture infiltration from the edge of the substrate 200 is blocked by the second passivation layer 240. The elongated path (in dash line) of the moisture infiltration is a main factor for the decreased probability of the delamination. In view of the above, with respect to conventional techniques, the design of the second passivation layer 240 covering the sidewalls of the wafer passivation layer 222 and the first passivation layer 224 can enhance the reliability of the chip structure significantly.

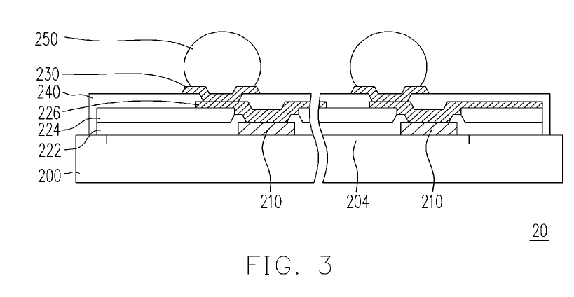

Also referring to FIG. 3, it is a schematic cross-sectional view of a chip structure in another embodiment of the present invention. In the present embodiment, a plurality of redistribution layers 226 can be formed on the bonding pads 210 through the patterning process and disposed between the first passivation layer 224 and the second passivation layer 240. Therefore, the bonding position of the under ball metal layers 230 can be changed by the redistribution layers 226, and the under ball metal layers 230 can be electrically connected to the corresponding bonding pads 210 by the redistribution layers 226.

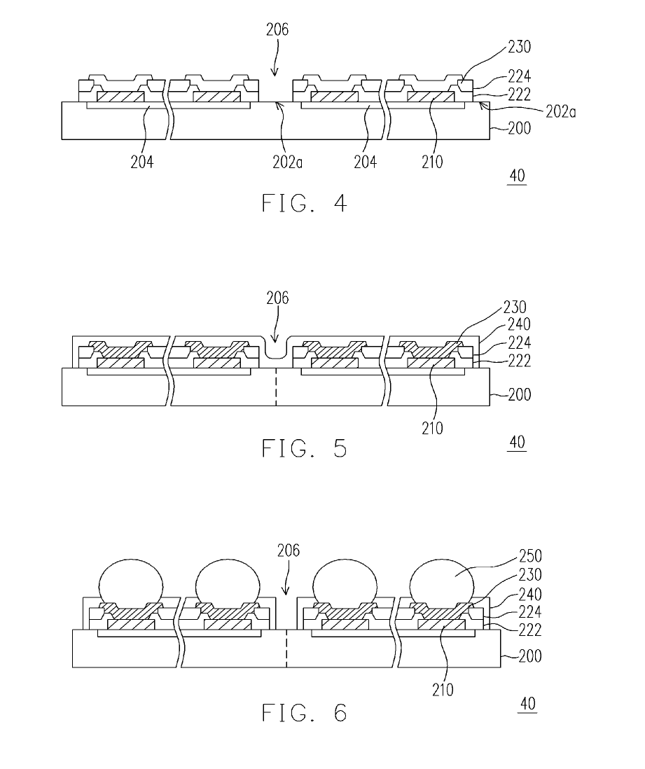

Next, the second passivation layer 240 employed in the present invention is further illustrated. Referring to FIGS. 4˜6, schematic views of the backend stage manufacturing processes of the chip structure are illustrated. Firstly, a wafer 40 with a preformed wafer passivation layer 222 thereon is provided, and the first passivation layer 224 is formed on the wafer passivation layer 222 and patterned to expose the bonding pads 210 and a portion of the active surface edge 202a. Next, an under ball metal layer 230 is formed on each of the bonding pads 210, to form the structure shown in FIG. 4. A scribe line 206 is disposed between the adjacent circuitry units 204 of the substrate 200 and exposed by the patterned first passivation layer 224. The redistribution layers 226 in FIG. 3 are not shown. However, it is known to those skilled in the art that the formation of the redistribution layer 226 includes forming a patterned circuitry layer (not shown) before forming the under ball metal layer 230, and then defining the bonding position of the under ball metal layer 230. The details will not be shown herein.

Next, referring to FIG. 5, a second passivation layer 240 is formed on the first passivation layer 224 and over the scribe line 206, such that the second passivation layer 240 can conformally cover the first passivation layer 224 and the sidewall of the wafer passivation layer 222. Then, referring to FIG. 6, a portion of the second passivation layer 240 is removed by patterning so as to expose the under ball metal layer 230, but the portion of the second passivation layer covering the sidewall of the first passivation layer 220 is still remained. Finally, after the manufacturing process of the bump 250 is completed, the wafer can be cut along the scribe line 206, to form a plurality of chip structures.

In view of the above, the present invention provides a chip structure and manufacturing process thereof. The feature is that the chip structure has a first passivation layer covering a substrate of the chip and exposing each of bonding pads and a portion of active surface, and a second passivation layer covering the first passivation layer. The second passivation layer covers the sidewalls of the first passivation layer and covers completely or partially the portion of active surface that is exposed by the first passivation layer, to prevent moisture infiltration from the edge of the substrate, and further decrease the probability of delamination between the passivation layers. Therefore, the reliability of the chip structure is enhanced.

The present invention is thus described with the above preferred embodiments, but not limit to this. It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A chip structure, comprising:
a substrate having an active surface;
a plurality of bonding pads disposed on the active surface;
a first passivation layer disposed on the active surface and exposing the bonding pads;
a plurality of under ball metal layers, each of the under ball metal layers connected to one of the bonding pads respectively; and
a second passivation layer disposed on the first passivation layer, wherein the second passivation layer covers a sidewall of the first passivation layer, and exposes the under ball metal layers.

2. The chip structure as claimed in claim 1, wherein the first passivation layer exposes an edge of the active surface, and the second passivation layer covers a portion of the exposed edge of the active surface.

3. The chip structure as claimed in claim 1, wherein the first passivation layer exposes an edge of the active surface, and the second passivation layer fully covers the exposed edge of the active surface.

4. The chip structure as claimed in claim 1, wherein a material of the first passivation layer is polyimide (PI) or benzocyclobutene (BCB).

5. The chip structure as claimed in claim 1, wherein a material of the second passivation layer is polyimide (PI) or benzocyclobutene (BCB).

6. The chip structure as claimed in claim 1, further comprising a plurality of bumps, each of the bumps being disposed on one of the under ball metal layers respectively.

7. The chip structure as claimed in claim 1, further comprising a plurality of redistribution layers disposed between the first passivation layer and the second passivation layer, each of the redistribution layers being connected to one of the bonding pads and one of the under ball metal layers respectively.

8. The chip structure as claimed in claim 1, further comprising a wafer passivation layer disposed between the substrate and the first passivation layer and exposing the bonding pads.

9. A wafer manufacturing process, comprising:
providing a wafer having a substrate, a plurality of bonding pads and a wafer passivation layer, wherein the substrate has an active surface, the bonding pads are disposed on the active surface, and the wafer passivation layer covers the active surface and exposes the bonding pads;
forming a first passivation layer over the wafer to cover the wafer passivation layer and the bonding pads;
patterning the first passivation layer to expose the bonding pads and a portion of the active surface;
forming a plurality of under ball metal layers, each of the under ball metal layers being connected to one of the bonding pads correspondingly;
forming a second passivation layer over the wafer; and
patterning the second passivation layer to expose the under ball metal layers and a portion of the active surface that is exposed by the first passivation layer, wherein the second passivation layer covers a sidewall of the first passivation layer.

10. The wafer manufacturing process as claimed in claim 9, further comprising forming a plurality of redistribution layers before the under ball metal layers are formed, wherein the redistribution layers are disposed between the first passivation layer and the second passivation layer, and each of the redistribution layers is connected to one of the bonding pads and one of the under ball metal layers respectively.

11. The wafer manufacturing process as claimed in claim 10, wherein a method of forming the redistribution layers comprises:
forming a metal layer on the first passivation layer; and
patterning the metal layer.
